(19) United States
(12) Patent Application Publication
(10) Pub. No.: US 2025/0211205 A1
(43) Pub. Date: Jun. 26, 2025

(54) Front-End Module

(71) Applicant: Sanan Japan Technology Corporation, Tokyo (JP)

(72) Inventors: Hitoshi Ebihara, Tokyo (JP); Shinichi SHIOI, Tokyo (JP)

(21) Appl. No.: 18/988,937

(22) Filed: Dec. 20, 2024

(30) Foreign Application Priority Data
Dec. 24, 2023 (JP) 2023-217505
Dec. 26, 2023 (JP) 2023-220044

(51) Int. Cl. H03H 9/64; H03H 9/02; H04B 1/40

(52) U.S. Cl. CPC H03H 9/64; H03H 9/02559; H04B 1/40

(57) ABSTRACT

The present application discloses a front-end module comprising: A first elastic wave device connected to an antenna terminal and configured to pass a first frequency band; A second elastic wave device connected to the antenna terminal and configured to pass a second frequency band; A third elastic wave device connected to the antenna terminal and configured to pass a third frequency band; A capacitive element connected to the antenna terminal; The switch for toggling the connection between the antenna terminal and the elastic wave device; The switch for toggling the connection between the antenna terminal and the capacitive element. The frequencies of the second frequency band and the third frequency band are higher than that of the first frequency band. The resonant frequency of the capacitive element is higher than the frequency of the first frequency band but lower than the frequencies of the second and third frequency bands.

### CROSS-REFERENCE TO RELATED APPLICATION

The present disclosure claims priority to Japanese Application No. 2023-217505 filed Dec. 24, 2023, and No. 2023-220044 filed Dec. 26, 2023, the contents of which are herein incorporated by reference in its entirety.

### FIELD

This application relates to a high-frequency front-end module for transmitting and receiving communication signals across multiple communication frequency bands.

### BACKGROUND

Mobile communication terminals, exemplified by smartphones, provide various telecommunication functions such as voice calls, video streaming, data transfer, messaging, and broadcasting. To enable these telecommunication functions, high-frequency front-end modules capable of operating across multiple frequency bands, each corresponding to different frequency ranges, are required.

A known high-frequency front-end module capable of utilizing multiple communication frequency bands includes electronic systems employing carrier aggregation (e.g., see Patent Document 1).

In FIG. 2C of Patent Document 1, an electronic system is described, comprising an antenna, a diplexer, and two power amplifiers (a first power amplifier and a second power amplifier).

In the described electronic system, the diplexer is connected to the antenna. Additionally, in this electronic system, each of the two power amplifiers is connected to the diplexer via a transmit/receive switch and a filter.
[Patent Document 1] JP2017-17691A.

### SUMMARY

A front-end module that supports carrier aggregation typically comprises three or more bandpass filters, but designing the equivalent capacitance of each bandpass filter is challenging. This application aims to construct a front-end module with a simpler structure that facilitates the design of equivalent capacitance for bandpass filters while supporting carrier aggregation.

To address the above issues, the present disclosure provides:

A front-end module, comprising:
an antenna terminal, a first elastic wave device, a second elastic wave device, a third elastic wave device, a capacitive element, a first switch, a second switch, a third switch, and a fourth switch;
the first elastic wave device is connected to the antenna terminal and configured to pass a first frequency band;
the second elastic wave device is connected to the antenna terminal and configured to pass a second frequency band;
the third elastic wave device is connected to the antenna terminal and configured to pass a third frequency band;
the capacitive element is connected to the antenna terminal;
the first switch is configured to switch between a closed state and an open state between the antenna terminal and the first elastic wave device;
the second switch is configured to switch between a closed state and an open state between the antenna terminal and the second elastic wave device;
the third switch is configured to switch between a closed state and an open state between the antenna terminal and the third elastic wave device;
the fourth switch is configured to switch between a closed state and an open state between the antenna terminal and the capacitive element;
wherein the second frequency band and the third frequency band have higher frequencies than the first frequency band;
the capacitive element is either a capacitor element or a resonator;
when the capacitive element is a resonator, the resonant frequency of the resonator is higher than the frequency of the first frequency band but lower than the frequencies of the second and third frequency bands.

Accordingly, the present application enables the construction of a front-end module that supports carrier aggregation with a simpler structure and facilitates the design of equivalent capacitance for bandpass filters.

The details of one or more embodiments of the present application are set forth in the accompanying drawings and the description below. Other features, objects, and advantages of the present application will be apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a schematic diagram of the front-end module 1 in Embodiment 1.

FIG. 2 is a characteristic diagram of the front-end module 1 in Embodiment 1 when the first switch SW1 and the fourth switch SW4 are closed.

FIG. 3 is a characteristic diagram of the front-end module 1 in Embodiment 1 when the first switch SW1 and the second switch SW2 are closed.

FIG. 4 is a characteristic diagram of the front-end module 1 in Embodiment 1 when the first switch SW1 and the third switch SW3 are closed.

FIG. 5 is a second characteristic diagram of the front-end module 1 in Embodiment 1 when the first switch SW1 and the fourth switch SW4 are closed.

FIG. 6 is a second characteristic diagram of the front-end module 1 in Embodiment 1 when the first switch SW1 and the second switch SW2 are closed.

FIG. 7 is a second characteristic diagram of the front-end module 1 in Embodiment 1 when the first switch SW1 and the third switch SW3 are closed.

FIG. 8 is an example of a bandpass filter, showing the elastic surface wave resonator used in a surface acoustic wave filter.

FIG. 9 is an example of a bandpass filter, showing the piezoelectric thin-film resonator used in an elastic wave filter.

FIG. 10 is a schematic diagram of the front-end module 1 in Embodiment 2.

FIG. 11 is a schematic diagram of the resonator R in the front-end module 1 in Embodiment 3.

FIG. 12 is a characteristic diagram of the front-end module 1 in Embodiment 3 when the first switch SW1 and the fourth switch SW4 are closed.

FIG. 13 is a schematic diagram of the front-end module 4 in Embodiment 4.

FIG. 14 is a schematic diagram of the front-end module 5 in Embodiment 5.

FIG. 15 is a schematic diagram of the front-end module 6 in Embodiment 6.

FIG. 16 is a schematic diagram of the front-end module 7 in Embodiment 7.

### DETAILED DESCRIPTION

For a better understanding of the objectives, technical solutions, and advantages of the present application, the following description and accompanying drawings provide further details.

Unless otherwise defined, technical or scientific terms used herein should have the same meanings as understood by those skilled in the art to which this application belongs. In this application, terms such as “a,” “an,” “one,” “the,” “these,” and similar expressions are not intended to limit the quantity; they can refer to either the singular or plural. Terms such as “comprising,” “including,” “having,” and their variations are intended to cover non-exclusive inclusions. For example, a process, method, or system, product, or device that includes a list of steps or modules is not limited to only those listed steps or modules but may include other steps or modules not listed or inherent in those processes, methods, systems, products, or devices. In this application, terms such as “connected,” “coupled,” and similar expressions are not limited to physical or mechanical connections but may include electrical connections, whether direct or indirect. The term “plurality” refers to two or more. “And/or” describes the relationship of associated objects, indicating that there are three possible relationships, such as “A and/or B” may indicate: the presence of A alone, the presence of both A and B, or the presence of B alone. Generally, the character “/” indicates an “or” relationship between the associated objects. Terms such as “first,” “second,” “third,” etc., are used for distinguishing similar objects and do not indicate specific orders.

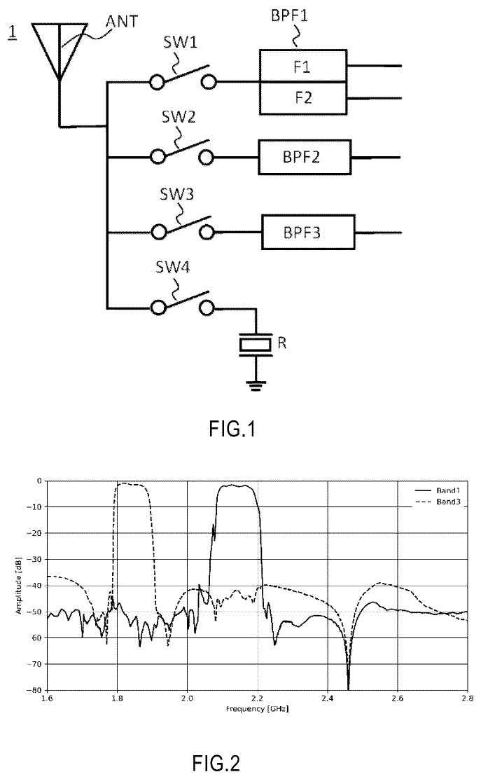

The following describes exemplary embodiments of this application with reference to FIGS. 1 to 16.

### Embodiment 1

FIG. 1 illustrates a schematic diagram of the front-end module 1 in Embodiment 1. As shown in FIG. 1, the front-end module 1 includes an antenna terminal (ANT), a first switch (SW1), a second switch (SW2), a third switch (SW3), a fourth switch (SW4), a first elastic wave device (BPF1), a second elastic wave device (BPF2), a third elastic wave device (BPF3), and a resonator (R) serving as a capacitive element. It should be noted that in other embodiments, the capacitive element may also be a capacitor element.

Switches SW1 through SW4 are used to switch connections between the antenna terminal ANT and elastic wave devices BPF1 to BPF3 as well as the resonator R.

Elastic wave devices BPF1 to BPF3, for example, form bandpass filters that allow only the desired frequency band of the applied electrical signal to pass.

The first elastic wave device BPF1 includes a first filter (F1) and a second filter (F2).

The first filter F1 is, for example, a bandpass filter that serves as a receive band for Band 1. It has a center frequency of 2140 MHz and allows frequencies in the range of 2110 MHz to 2170 MHz to pass.

The second filter F2 is, for example, a bandpass filter that serves as a receive band for Band 3. It has a center frequency of 1842.5 MHz and allows frequencies in the range of 1805 MHz to 1880 MHz to pass.

The second elastic wave device BPF2 is, for example, a bandpass filter that serves as a receive band for Band 7. It has a center frequency of 2655 MHz and allows frequencies in the range of 2620 MHz to 2690 MHz to pass.

The third elastic wave device BPF3 is, for example, a bandpass filter that serves as a receive band for Band 41. It has a center frequency of 2593 MHz and allows frequencies in the range of 2496 MHz to 2690 MHz to pass.

The passbands of the second elastic wave device BPF2 and the third elastic wave device BPF3 partially overlap. Therefore, the second elastic wave device BPF2 and the third elastic wave device BPF3 are not used simultaneously. In other words, the second switch SW2 and the third switch SW3 are not closed at the same time.

This is because closing elastic wave devices with partially overlapping frequency bands simultaneously can result in significant impedance mismatch. Additionally, even if the frequency bands do not overlap, elastic wave devices with passband frequencies close enough to cause difficulty in achieving impedance matching are not used simultaneously.

For example, elastic wave devices with passband frequencies differing by only about 25 MHz are considered too close to achieve impedance matching effectively.

In the front-end module 1 of Embodiment 1, the equivalent input capacitance (EC) of the first elastic wave device BPF1, which is the equivalent capacitance at specific frequencies, is configured to be smaller than the equivalent input capacitance of the resonator R at frequencies outside the passbands of the second elastic wave device BPF2 and the third elastic wave device BPF3.

The resonant frequency of the resonator R, for example, is set at 2470 MHz. The resonant frequency of the resonator R is higher than the frequencies of Bands 1 and 3 but lower than the frequencies of Bands 7 and 41. For instance, the resonant frequency of the resonator R is set at 2470 MHz.

FIG. 2 illustrates the characteristic diagram of the front-end module 1 in Embodiment 1 when the first switch SW1 and the fourth switch SW4 are closed.

As shown in FIG. 2, when the first switch SW1 and the fourth switch SW4 are closed, a favorable impedance matching condition can be achieved on the antenna side, ensuring excellent passband characteristics. Additionally, strong attenuation characteristics can be achieved at the resonant frequency of the resonator R.

Moreover, the equivalent capacitance (EC) of the first elastic wave device BPF1 at frequencies outside its passband is configured to be smaller than the equivalent input capacitance of the second elastic wave device BPF2 and the third elastic wave device BPF3 at specific frequencies.

With this configuration, regardless of which of the switches SW1 to SW4 is in a closed state, favorable impedance matching can always be achieved on the antenna side.

The equivalent capacitance (EC) here refers to the equivalent input capacitance at a specific frequency. By expressing the imaginary part (reactance) of the input impedance of the filter as X, and the frequency as f, the equivalent capacitance can be calculated using the following Equation.

$$EC = 1 / ( 2 * π * f * X ) \qquad ( Equation 1 )$$

In addition, the equivalent input capacitances of the second elastic wave device BPF2 and the third elastic wave device BPF3 are configured to be equivalent at the center frequency of the first elastic wave device BPF1.

The equivalent input capacitance mentioned here refers to the equivalent input capacitance at a specific frequency, calculated using Equation 1 provided above.

TABLE 1

| SW1 | SW2 | SW3 | SW4 | BPF1 | BPF2 | BPF3 | EX. |
|---|---|---|---|---|---|---|---|
| ON | ON | OFF | OFF | ON | ON | OFF | B1 or |
| | | | | | | | B3 + B7 |
| ON | OFF | ON | OFF | ON | OFF | ON | B1 or |
| | | | | | | | B3 + B41 |
| ON | OFF | OFF | ON | ON | OFF | OFF | B1 or B3 |
| OFF | ON | OFF | OFF | OFF | ON | OFF | B7 |
| OFF | OFF | ON | OFF | OFF | OFF | ON | B41 |

Table 1 outlines the usage of the elastic wave devices BPF1 to BPF3 and the open/closed states of switches SW1 to SW4. When the first switch SW1 and the second switch SW2 are closed simultaneously, or when only the second switch SW2 or the third switch SW3 is closed, the fourth switch SW4 remains open.

Additionally, when only the first switch SW1 is closed, the fourth switch SW4 is also closed. At least one of the switches SW1 to SW3 is always in a closed state. Furthermore, the second switch SW2 and the third switch SW3 are never closed simultaneously.

In a front-end module supporting carrier aggregation, the equivalent input capacitance ideally remains consistent across all connection configurations of the elastic wave devices, ensuring impedance consistency in all states. For example, when Band 3 (B3) is used simultaneously with Band 7 (B7) or Band 41 (B41), the equivalent input capacitance of Band 3 accounts for the influence of the equivalent input capacitance of Band 7 or Band 41. Therefore, the resonator R does not need to be connected.

If the equivalent input capacitances of Band 7 and Band 41 are equal at the center frequency of Band 3, the configuration of Band 3 considering equivalent input capacitance is optimized. For instance, in the case of Band 7 and Band 41, Band 3 is optimized when the equivalent input capacitance is 1.4 pF.

Since the passbands of Band 7 and Band 41 overlap, they are not used simultaneously. Thus, when Band 7 or Band 41 is used individually, Band 3 can be disconnected and optimized independently.

When Band 1 (B1) or Band 3 is used individually, the resonator R can replace the equivalent input capacitance of Band 7 or Band 41. This ensures the influence of equivalent input capacitance is accounted for. As shown in FIG. 2, this allows performance optimization of Bands 1 and 3 without altering their optimized configurations.

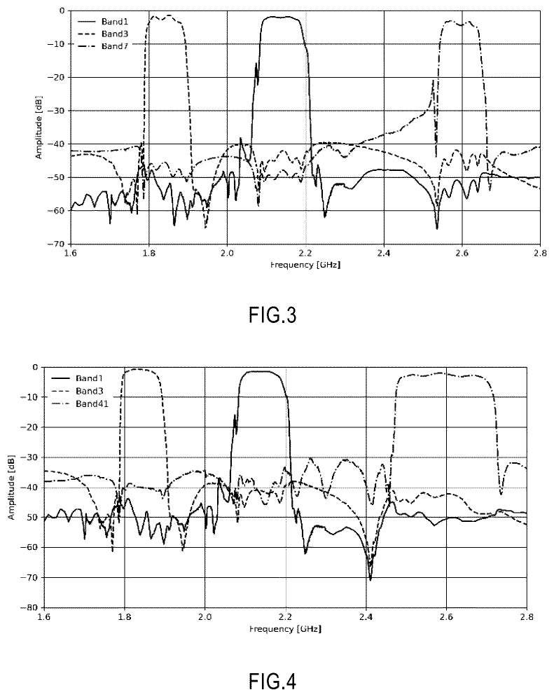

FIG. 3 depicts the characteristics of the front-end module 1 in Embodiment 1 when the first switch SW1 and the second switch SW2 are closed. As shown in FIG. 3, favorable impedance matching and excellent passband characteristics can be achieved on the antenna side when SW1 and SW2 are closed.

FIG. 4 illustrates the characteristics of the front-end module 1 in Embodiment 1 when the first switch SW1 and the third switch SW3 are closed. As shown in FIG. 4, favorable impedance matching and excellent passband characteristics can also be achieved on the antenna side in this configuration.

FIG. 5 to 7 present the characteristics of the front-end module 1, highlighting the properties of the first elastic wave device BPF1:

The first filter F1 provides a passband for Band 34, a bandpass filter with a center frequency of 2117.5 MHz that allows frequencies between 2110 MHz and 2125 MHz to pass.

The second filter F2 provides a passband for Band 39, a bandpass filter with a center frequency of 1900 MHz that allows frequencies between 1880 MHz and 1920 MHz to pass.

FIG. 5 shows the characteristics of the front-end module 1 in Embodiment 1 (second view) when the first switch SW1 and the fourth switch SW4 are closed.

As depicted in FIG. 5, even when other bands are used for the first elastic wave device BPF1, favorable impedance matching and excellent passband characteristics can still be achieved on the antenna side when SW1 and SW4 are closed. Strong attenuation characteristics can also be realized at the resonant frequency of the resonator R.

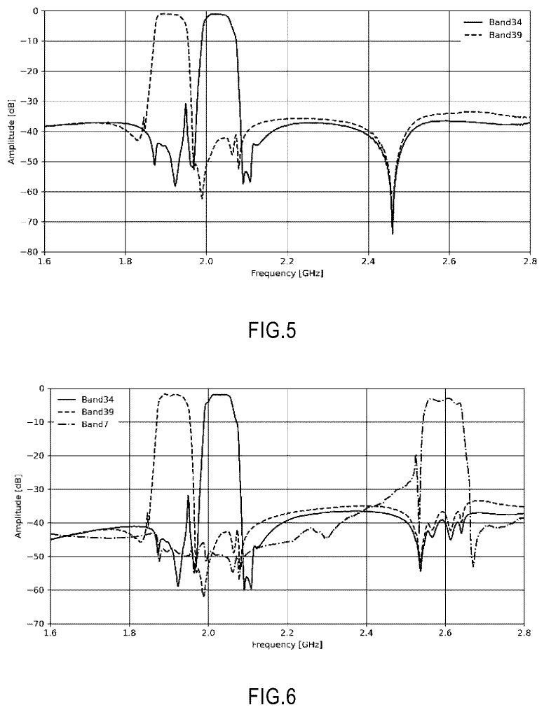

FIG. 6 depicts the characteristics of the front-end module 1 in Embodiment 1 (second view) when the first switch SW1 and the second switch SW2 are closed. In this case, Band 34 is used for the first filter F1, and Band 39 is used for the second filter F2. As shown in FIG. 6, even when other bands are used for the first elastic wave device BPF1, favorable impedance matching and excellent passband characteristics can still be achieved on the antenna side when SW1 and SW2 are closed.

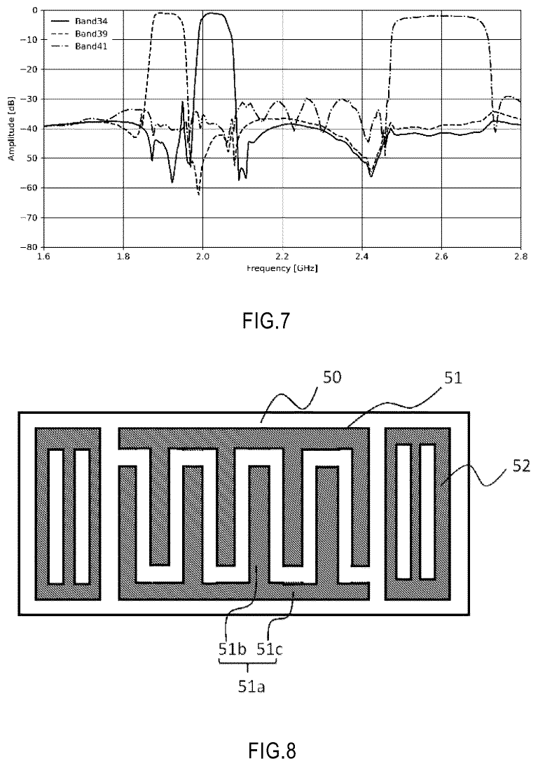

FIG. 7 shows the characteristics of the front-end module 1 in Embodiment 1 (second view) when the first switch SW1 and the third switch SW3 are closed. In this case, Band 34 is used for the first filter F1, and Band 39 is used for the second filter F2. As shown in FIG. 7, even when other bands are used for the first elastic wave device BPF1, favorable impedance matching and excellent passband characteristics can still be achieved on the antenna side when SW1 and SW3 are closed.

FIG. 8 illustrates an example of a bandpass filter, specifically an elastic surface wave resonator used in a surface acoustic wave (SAW) filter. The elastic surface wave resonator comprises an interdigital transducer (IDT) 51 and reflectors 52, both formed on a piezoelectric substrate 50. The IDT 51 includes a pair of opposing comb electrodes 51a.

For example, the comb electrodes 51a consist of multiple electrode fingers 51b connected by a bus bar 51c. The reflectors 52 are positioned on both sides of the IDT 51, sandwiching it. The IDT 51 excites surface acoustic waves. The piezoelectric substrate 50 may be, for example, a lithium tantalate substrate or a lithium niobate substrate. The IDT 51 and reflectors 52 are formed from materials such as aluminum film or copper film.

The piezoelectric substrate 50 can also be bonded to a supporting substrate such as a sapphire substrate, aluminum oxide substrate, spinel substrate, or silicon substrate. Additionally, a protective film or a temperature compensation film can be applied over the IDT 51 and the reflectors 52.

When any of the elastic wave devices BPF1 to BPF3 employs a SAW filter, the resonator R can be implemented as a SAW resonator on the device chip that includes the elastic wave device using the SAW filter.

Furthermore, when multiple elastic wave devices using SAW filters are present, it is preferable to form the resonator R on the device chip of the elastic wave device whose frequency is closest to the resonant frequency of the resonator R. This is because the device chip is already optimized for its frequency band, including the cut angle and thickness of the piezoelectric substrate, as well as the thickness of the IDT electrodes. For instance, the resonator R can be implemented as a SAW resonator on the device chip equipped with the highest-frequency SAW filter.

FIG. 9 illustrates another example of a bandpass filter, showing a piezoelectric thin-film resonator used in an elastic wave filter. This piezoelectric thin-film resonator includes a piezoelectric film 57 situated on a substrate 55. A lower electrode 56 and an upper electrode 58 are positioned on either side of the piezoelectric film 57, with a gap 59 formed between the lower electrode 56 and the substrate 55.

The lower electrode 56 and the upper electrode 58 excite a thickness-extensional vibration mode of elastic waves in the piezoelectric film 57. The lower and upper electrodes are typically made of metal films, such as ruthenium film. The piezoelectric film 57 can be, for example, an aluminum nitride film. The substrate 55 may be made of materials such as silicon, sapphire, aluminum oxide, spinel, or glass.

Elastic wave resonators may also adopt structures different from those shown in FIGS. 8 and 9, such as alternative configurations that achieve similar functionality.

The front-end module 1 of Embodiment 1 described above features a simpler structure, enabling the construction of a front-end module that supports carrier aggregation while facilitating the design of the equivalent capacitance for the bandpass filters.

### Embodiment 2

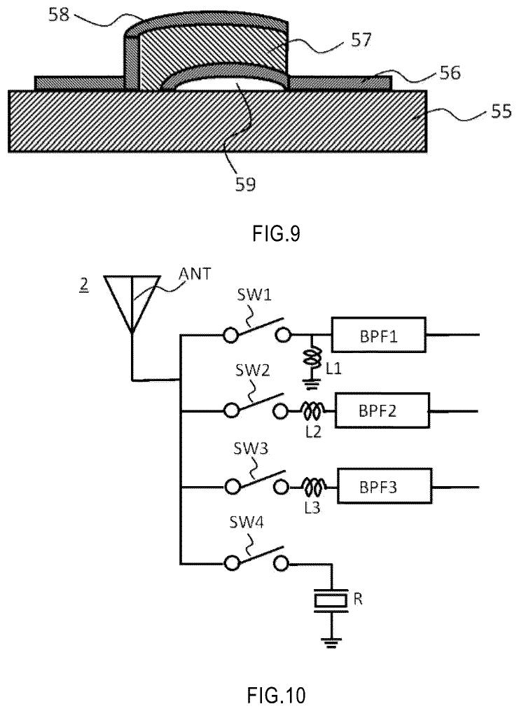

FIG. 10 illustrates a schematic diagram of the front-end module 2 in Embodiment 2. As shown in FIG. 10, the front-end module 2 includes an antenna terminal (ANT), a first switch (SW1), a second switch (SW2), a third switch (SW3), a fourth switch (SW4), a first elastic wave device (BPF1), a second elastic wave device (BPF2), a third elastic wave device (BPF3), a first inductor element (L1), a second inductor element (L2), a third inductor element (L3), and a resonator (R) serving as a capacitive element.

The first inductor element (L1) is connected between the first switch SW1 and the first elastic wave device BPF1 and is grounded. The second inductor element (L2) is connected in series between the second switch SW2 and the second elastic wave device BPF2. The third inductor element (L3) is connected in series between the third switch SW3 and the third elastic wave device BPF3. The other structures are the same as those in the front-end module 1 of Embodiment 1.

As described in Embodiment 1, the first elastic wave device BPF1 includes a bandpass filter for lower frequencies compared to the second elastic wave device BPF2 and the third elastic wave device BPF3.

Since the first elastic wave device BPF1 is a low-frequency filter in the front-end module 2, its capacitive component is relatively large, necessitating a reduction in its capacitance. By connecting a inductor element in parallel, it is possible to offset all or part of the capacitance of the first elastic wave device BPF1. For example, the first inductor element L1 can be set to 5 nH.

Conversely, since the second elastic wave device BPF2 and the third elastic wave device BPF3 are high-frequency filters, their capacitive components are relatively small. Therefore, it is desirable to increase the capacitance of the second and third elastic wave devices. By connecting inductor elements in series, the capacitive components of the second elastic wave device BPF2 and the third elastic wave device BPF3 can appear larger, making it easier to adjust their equivalent input capacitance. For example, the second inductor element L2 and the third inductor element L3 can be set to 3 nH.

The equivalent input capacitances of the second elastic wave device BPF2 and the third elastic wave device BPF3 are configured to be equivalent at the center frequency of the first elastic wave device BPF1, considering the inductance values of the second inductor element L2 and the third inductor element L3.

The front-end module 2 of Embodiment 2 maintains a simple structure while achieving adjustments solely by adding inductive elements. This configuration enables the construction of a front-end module that supports carrier aggregation and simplifies the design of the bandpass filters.

### Embodiment 3

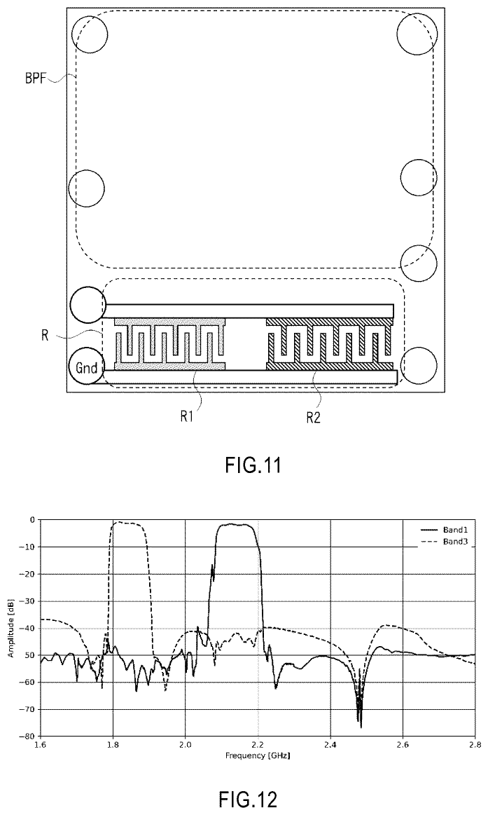

FIG. 11 illustrates a schematic diagram of the resonator R in the front-end module 3 of Embodiment 3. As shown in FIG. 11, the resonator R can be divided in parallel into a first resonator R1 and a second resonator R2. The resonator R, as shown in FIG. 11, can also adopt a structure sandwiched between a pair of reflectors.

The resonant frequencies of the first resonator R1 and the second resonator R2 can be set to different values. For example, the frequency difference between the resonant frequencies of the first resonator R1 and the second resonator R2 can be set within a range of 25 MHz to 50 MHz to ensure sufficient attenuation characteristics and achieve wideband attenuation.

FIG. 12 shows the characteristic diagram of the front-end module 3 of Embodiment 3 when the first switch SW1 and the fourth switch SW4 are closed.

As shown in FIG. 12, when the first switch SW1 and the fourth switch SW4 are closed, favorable impedance matching and excellent passband characteristics can be achieved on the antenna side. Additionally, due to the resonant frequency of the first resonator R1 and the resonant frequency of the second resonator R2, which is different from that of the first resonator R1, good attenuation characteristics over a wider frequency band can be realized.

The front-end module 3 of Embodiment 3 maintains a simple structure while achieving excellent wideband attenuation characteristics. This configuration enables the construction of a front-end module that simplifies bandpass filter design and supports carrier aggregation.

### Embodiment 4

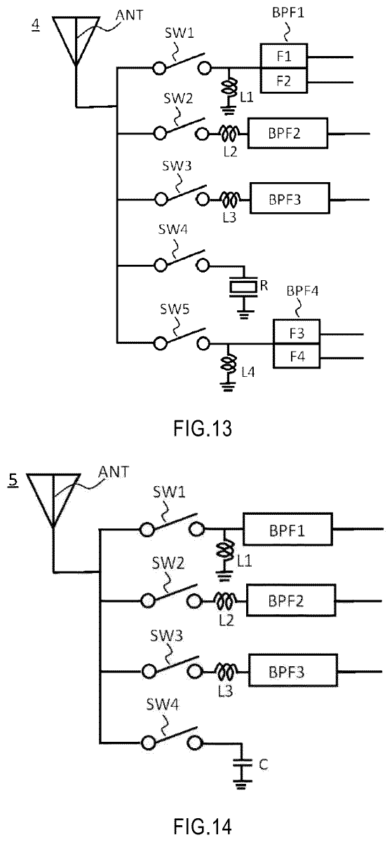

FIG. 13 illustrates a schematic diagram of the front-end module 4 in Embodiment 4. As shown in FIG. 13, the front-end module 4 includes the structures of the front-end modules 1 and 2 described in Embodiments 1 and 2, and further comprises a fourth elastic wave device (BPF4), a fifth switch (SW5), and a fourth inductor element (L4).

As shown in FIG. 13, the fifth switch SW5 is used to toggle the connection between the antenna terminal ANT and the fourth elastic wave device BPF4. The fourth inductor element L4 is connected between the fifth switch SW5 and the fourth elastic wave device BPF4.

The first elastic wave device BPF1 includes a first filter (F1) and a second filter (F2). Additionally, the fourth elastic wave device BPF4 includes a third filter (F3) and a fourth filter (F4).

The first filter F1, for example, is a bandpass filter for Band 3 with a center frequency of 1842.5 MHz, allowing frequencies in the range of 1805 MHz to 1880 MHz to pass.

The second filter F2, for example, is a bandpass filter for Band 1 with a center frequency of 2140 MHz, allowing frequencies in the range of 2110 MHz to 2170 MHz to pass.

As described earlier, the second elastic wave device BPF2 corresponds to Band 7 with a center frequency of 2655 MHz, while the third elastic wave device BPF3 corresponds to Band 41 with a center frequency of 2593 MHz. The average of these center frequencies is 2624 MHz.

The first filter F1 and the first inductor element L1 are designed to achieve an equivalent input capacitance satisfying the conditions described later at the average center frequency of 2624 MHz, calculated using Equation 1. Similarly, the second filter F2 and the first inductor element L1 are also designed to meet the same conditions.

Since the frequency of the first filter F1 is lower than that of the second filter F2, its equivalent input capacitance at the average center frequency of 2624 MHz is smaller.

The third filter F3, for example, is a bandpass filter for Band 39 with a center frequency of 1900 MHz, allowing frequencies in the range of 1880 MHz to 1920 MHz to pass.

The fourth filter F4, for example, is a bandpass filter for Band 34 with a center frequency of 2117.5 MHz, allowing frequencies in the range of 2110 MHz to 2125 MHz to pass.

The center frequency of the first filter F1 (1805 MHz-1880 MHz) and the third filter F3 (1880 MHz-1920 MHz) is 1872 MHz.

The center frequency of the second filter F2 (2110 MHz-2170 MHz) and the fourth filter F4 (2110 MHz-2125 MHz) is 2129 MHz.

The third filter F3 and the fourth inductor element L4 are designed to achieve an equivalent input capacitance satisfying the conditions described later at the average center frequency of 2624 MHz. The equivalent input capacitance is calculated using Equation 1.

Similarly, the fourth filter F4 and the fourth inductor element L4 are designed to meet the same conditions.

Since the frequency of the third filter F3 is lower than that of the fourth filter F4, its equivalent input capacitance at the average center frequency of 2624 MHz is smaller.

The equivalent input capacitance of the second elastic wave device BPF2 at the center frequency of 1872 MHz (determined by the first filter F1 and the third filter F3) is greater than the equivalent input capacitance of the filters F1 to F4 at the average center frequency of 2624 MHz.

Similarly, the equivalent input capacitance of the third elastic wave device BPF3 at the center frequency of 1872 MHz is greater than the equivalent input capacitance of the filters F1 to F4 at the average center frequency of 2624 MHz.

Additionally, at the center frequency of 1872 MHz, the sum of the equivalent input capacitance of the second filter F2 or the fourth filter F4 and the equivalent input capacitance of the second elastic wave device BPF2 preferably matches the absolute value of the impedance of the first inductor element L1 at 1872 MHz.

At the center frequency of 2129 MHz (determined by the second filter F2 and the fourth filter F4), the sum of the equivalent input capacitance of the first filter F1 or the third filter F3 and the equivalent input capacitance of the second elastic wave device BPF2 preferably matches the absolute value of the impedance of the first inductor element L1 at 2129 MHz.

At the average center frequency of 2624 MHz, the sum of the equivalent input capacitance of the first filter F1 or the third filter F3 and the equivalent input capacitance of the second filter F2 or the fourth filter F4 preferably matches the absolute value of the impedance of the first inductor element L1 at 2624 MHz.

Since the fourth elastic wave device BPF4 has a passband frequency lower than that of the second elastic wave device BPF2, its capacitive component is relatively large. Therefore, it is desirable to reduce the capacitive component of the fourth elastic wave device BPF4. By connecting the inductor element in parallel, the entire or partial capacitive component of the fourth elastic wave device BPF4 can be offset.

As a result, regardless of which switch SW1 to SW5 is closed, favorable impedance matching can always be achieved on the antenna side by using the fourth inductor element L4, which is connected between the fifth switch SW5 and the fourth elastic wave device BPF4 and is grounded.

TABLE 2

| | | | | | | | | | |
|---|---|---|---|---|---|---|---|---|---|
| SW1 | SW2 | SW3 | SW4 | SW5 | BPF1 | BPF2 | BPF3 | BPF4 | EX. |

| | | | | | | | | | |
|---|---|---|---|---|---|---|---|---|---|
| ON | ON | OFF | OFF | OFF | ON | ON | OFF | OFF | B1 or |
| | | | | | | | | | B3 + B7 |
| ON | OFF | ON | OFF | OFF | ON | OFF | ON | OFF | B1 or |
| | | | | | | | | | B3 + B41 |
| OFF | ON | OFF | OFF | ON | OFF | ON | OFF | ON | B34 or |
| | | | | | | | | | B39 + B7 |
| OFF | OFF | ON | OFF | ON | OFF | OFF | ON | ON | B34 or |
| | | | | | | | | | B39 + |
| | | | | | | | | | B41 |
| ON | OFF | OFF | ON | OFF | ON | OFF | OFF | OFF | B1 or B3 |
| OFF | ON | OFF | OFF | OFF | OFF | ON | OFF | OFF | B7 |
| OFF | OFF | ON | OFF | OFF | OFF | OFF | ON | OFF | B41 |
| OFF | OFF | OFF | ON | ON | OFF | OFF | OFF | ON | B34 or |
| | | | | | | | | | B39 |

Table 2 outlines the usage of the elastic wave devices BPF1 to BPF4 and the open/closed states of switches SW1 to SW5.

When the second switch SW2 and the fifth switch SW5 are closed simultaneously, or when the third switch SW3 and the fifth switch SW5 are closed simultaneously, the fourth switch SW4 remains open.

Additionally, when only the fifth switch SW5 is closed, the fourth switch SW4 is also closed. At least one of the switches SW1 to SW3 and SW5 is always in a closed state. Furthermore, the second switch SW2 and the third switch SW3 are never closed simultaneously, and neither are the first switch SW1 and the fifth switch SW5.

For example, when Band 39 (B39) is used simultaneously with Band 7 (B7) or Band 41 (B41), the equivalent input capacitance of Band 39 accounts for the influence of the equivalent input capacitance of Band 7 or Band 41. Therefore, there is no need to connect the resonator R.

If the equivalent input capacitances of Band 7 and Band 41 are equivalent at the center frequency of Band 39, the configuration of Band 39, considering the equivalent input capacitance, is optimized. For example, in the case of Band 7 and Band 41, Band 39 is optimized when the equivalent input capacitance is 1.4 pF.

Since the passbands of Band 7 and Band 41 partially overlap, they are not used simultaneously. Thus, when Band 7 or Band 41 is used individually, the configuration can be optimized separately by disconnecting Band 39.

When Band 39 is used individually, the resonator R can be connected in place of the equivalent input capacitance of Band 7 or Band 41. This configuration accounts for the influence of the equivalent input capacitance while maintaining the optimized characteristics of Band 39 and fully realizing its performance.

In the front-end module 4 of Embodiment 4, for example, it is not envisioned that Band 3 and Band 39 would be used simultaneously, as their passband frequencies are too close to achieve impedance matching effectively.

The front-end module 4 of Embodiment 4, even when configured to include six bands, achieves a simplified structure that supports carrier aggregation. This design facilitates the equivalent capacitance adjustment of bandpass filters, making the design process significantly easier.

### Embodiment 5

FIG. 14 illustrates a schematic diagram of the front-end module 5 in Embodiment 5. As shown in FIG. 14, the front-end module 5 includes an antenna terminal (ANT), a first switch (SW1), a second switch (SW2), a third switch (SW3), a fourth switch (SW4), a first elastic wave device (BPF1), a second elastic wave device (BPF2), a third elastic wave device (BPF3), a first inductor element (L1), a second inductor element (L2), a third inductor element (L3), and a capacitive element (C) serving as a capacitive component.

Switches SW1 through SW4 are used to toggle connections between the antenna terminal ANT and the elastic wave devices BPF1 to BPF3, as well as the capacitive element C. The first inductor element L1 is connected between the first switch SW1 and the first elastic wave device BPF1 and is grounded. The second inductor element L2 is connected in series between the second switch SW2 and the second elastic wave device BPF2. The third inductor element L3 is connected in series between the third switch SW3 and the third elastic wave device BPF3.

The elastic wave devices BPF1 to BPF3 are bandpass filters designed to allow only the desired frequency bands of the applied signal to pass.

The first elastic wave device BPF1 is a bandpass filter for Band 3 with a center frequency of 1842.5 MHz, allowing frequencies in the range of 1805 MHz to 1990 MHz to pass.

The second elastic wave device BPF2 is a bandpass filter for Band 7 with a center frequency of 2655 MHz, allowing frequencies in the range of 2620 MHz to 2690 MHz to pass.

The third elastic wave device BPF3 is a bandpass filter for Band 41 with a center frequency of 2593 MHz, allowing frequencies in the range of 2496 MHz to 2690 MHz to pass.

Since the passbands of the second elastic wave device BPF2 and the third elastic wave device BPF3 partially overlap, these two devices are not used simultaneously. In other words, the second switch SW2 and the third switch SW3 are never closed at the same time.

If elastic wave devices with overlapping frequency bands are used simultaneously, significant impedance mismatches may occur. Additionally, even if their frequency bands do not overlap, elastic wave devices with passbands that are too close in frequency also cannot achieve proper impedance matching and are not used simultaneously.

For example, elastic wave devices with passbands that differ by approximately 25 MHz are considered to have frequencies close enough to make impedance matching difficult.

The first elastic wave device BPF1, being a low-frequency filter, has a relatively large capacitance. To reduce its capacitance, a inductor element can be connected in parallel to offset all or part of its capacitive component. For example, the first inductor element L1 can be set to 5 nH.

The second and third elastic wave devices BPF2 and BPF3, being high-frequency filters, have relatively small capacitance. To make their capacitance appear larger, inductor elements can be connected in series. This adjustment makes it easier to optimize the equivalent input capacitance. For example, the second inductor element L2 and the third inductor element L3 can be set to 3 nH.

The equivalent input capacitance (EC) of the first elastic wave device BPF1 at frequencies outside the passbands of the second and third elastic wave devices is designed to be smaller than the equivalent input capacitance of the capacitive element C.

Regardless of which switch SW1 to SW4 is closed, favorable impedance matching can be achieved on the antenna side through the first inductor element L1, which is connected to the first elastic wave device BPF1 and is grounded.

Moreover, the equivalent capacitance EC of the first elastic wave device BPF1 at frequencies outside its passband is designed to be smaller than the equivalent input capacitances of the second elastic wave device BPF2 and the third elastic wave device BPF3, calculated as the equivalent capacitance EC at specific frequencies.

Therefore, regardless of which switch SW1 to SW4 is in a closed state, favorable impedance matching can be achieved at the antenna terminal through the first inductor element L1, which is connected to the first elastic wave device BPF1 and grounded.

The equivalent capacitance EC mentioned here refers to the equivalent input capacitance at a specific frequency. If the imaginary part of the filter's input impedance is represented as reactance X and the frequency as f, the equivalent capacitance can be calculated using Equation 1 described in Embodiment 1. The specific frequency referred to here is a frequency outside the passband of the filter.

Additionally, the equivalent input capacitances of the second elastic wave device BPF2 and the third elastic wave device BPF3 are adjusted to be equivalent at the center frequency of the first elastic wave device BPF1 by taking into account the inductance values of the second inductor element L2 and the third inductor element L3. The equivalent input capacitance mentioned here refers to the capacitance calculated at a specific frequency using Equation 1 described above.

TABLE 3

| SW1 | SW2 | SW3 | SW4 | BPF1 | BPF2 | BPF3 | EX. |
|---|---|---|---|---|---|---|---|
| ON | ON | OFF | OFF | ON | ON | OFF | B3 + B7 |
| ON | OFF | ON | OFF | ON | OFF | ON | B3 + B41 |
| ON | OFF | OFF | ON | ON | OFF | OFF | B3 |
| OFF | ON | OFF | OFF | OFF | ON | OFF | B7 |
| OFF | OFF | ON | OFF | OFF | OFF | ON | B41 |

Table 3 lists the usage of the elastic wave devices BPF1 to BPF3 and the switch states of SW1 to SW4. When the first switch SW1 and the second switch SW2 are closed simultaneously, when only the second switch SW2 is closed, or when only the third switch SW3 is closed, the fourth switch SW4 remains open.

Additionally, when only the first switch SW1 is closed, the fourth switch SW4 is also closed. At least one of the switches SW1 to SW3 is always in a closed state. Furthermore, the second switch SW2 and the third switch SW3 are never closed simultaneously.

In a front-end module that supports carrier aggregation, the equivalent input capacitance should remain the same regardless of the connection mode of the elastic wave devices, and the impedance should remain consistent in all connection states. For example, when Band 3 (B3) is used together with Band 7 (B7) or Band 41 (B41), there is no need to connect the capacitive element C because the design of Band 3 already accounts for the equivalent input capacitance of Band 7 or Band 41.

When the equivalent input capacitances of Band 7 and Band 41 are equal at the center frequency of Band 3, the configuration of Band 3, which considers the equivalent input capacitance, will be optimized. For instance, in the case of Band 7 and Band 41, the configuration of Band 3 is optimized when the equivalent input capacitance is 1.4 pF.

Since the passbands of Band 7 and Band 41 partially overlap, they are not used simultaneously. Therefore, when either Band 7 or Band 41 is used individually, optimization can be performed independently by disconnecting Band 3.

When Band 3 is used individually, the capacitive element C is connected to replace the equivalent input capacitance of Band 7 or Band 41. This accounts for the equivalent input capacitance and ensures that the optimized characteristics of the Band 3 configuration remain unchanged, allowing its performance to be fully realized.

The front-end module 5 of Embodiment 5, described above, features a simpler structure that enables the construction of a front-end module supporting carrier aggregation while simplifying the design of the equivalent input capacitance for bandpass filters.

### Embodiment 6

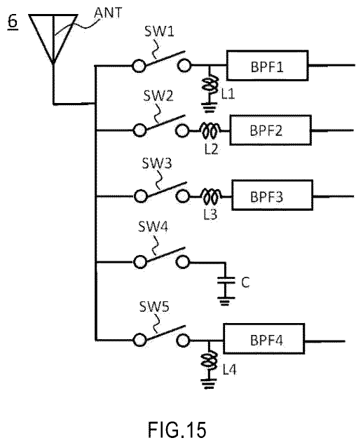

FIG. 15 illustrates a schematic diagram of the front-end module 6 in Embodiment 6. As shown in FIG. 15, the front-end module 6 builds upon the structure of the front-end module 5 described in Embodiment 5, with the addition of a fourth elastic wave device (BPF4), a fifth switch (SW5), and a fourth inductor element (L4).

The fifth switch SW5 is used to toggle the connection between the antenna terminal (ANT) and the fourth elastic wave device BPF4. The fourth inductor element L4 is connected between the fifth switch SW5 and the fourth elastic wave device BPF4 and is grounded.

The fourth elastic wave device BPF4, for example, is a bandpass filter for Band 39, with a center frequency of 1900 MHz, allowing frequencies in the range of 1880 MHz to 1920 MHz to pass. In other words, the passband frequency of the fourth elastic wave device BPF4 is lower than the passband frequency of the second elastic wave device BPF2. For instance, the fourth inductor element L4 can be set to 4.8 nH.

Since the passband of the fourth elastic wave device BPF4 is lower than that of the second elastic wave device BPF2, its capacitance is relatively large. Therefore, it is necessary to reduce the capacitance of the fourth elastic wave device BPF4. By connecting a inductor element in parallel, the entire or partial capacitance of the fourth elastic wave device BPF4 can be offset.

This configuration ensures that regardless of which switch SW1 to SW5 is in a closed state, favorable impedance matching can be achieved at the antenna terminal through the fourth inductor element L4, which is connected between the fifth switch SW5 and the fourth elastic wave device BPF4 and is grounded.

TABLE 4

| SW1 | SW2 | SW3 | SW4 | SW5 | BPF1 | BPF2 | BPF3 | BPF4 | EX. |
|---|---|---|---|---|---|---|---|---|---|
| ON | ON | OFF | OFF | OFF | ON | ON | OFF | OFF | B3 + B7 |
| ON | OFF | ON | OFF | OFF | ON | OFF | ON | OFF | B3 + B41 |
| OFF | ON | OFF | OFF | ON | OFF | ON | OFF | ON | B39 + B7 |
| OFF | OFF | ON | OFF | ON | OFF | OFF | ON | ON | B39 + |
| | | | | | | | | | B41 |
| ON | OFF | OFF | ON | OFF | ON | OFF | OFF | OFF | B3 |
| OFF | ON | OFF | OFF | OFF | OFF | ON | OFF | OFF | B7 |
| OFF | OFF | ON | OFF | OFF | OFF | OFF | ON | OFF | B41 |
| OFF | OFF | OFF | ON | ON | OFF | OFF | OFF | ON | B39 |

Table 4 outlines the usage of the elastic wave devices BPF1 to BPF4 and the switching states of SW1 to SW5.

When the second switch SW2 and the fifth switch SW5 are closed simultaneously, or when the third switch SW3 and the fifth switch SW5 are closed simultaneously, the fourth switch SW4 remains open.

Additionally, when only the fifth switch SW5 is closed, the fourth switch SW4 is in a closed state. At least one of the switches SW1 to SW3 and SW5 is always in a closed state. Furthermore, the second switch SW2 and the third switch SW3 are never closed simultaneously, and neither are the first switch SW1 and the fifth switch SW5.

For example, when Band 39 (B39) is used together with Band 7 (B7) or Band 41 (B41), there is no need to connect the capacitive element C, as the design of Band 39 already accounts for the equivalent input capacitance of Band 7 or Band 41.

When the equivalent input capacitances of Band 7 and Band 41 are equal at the center frequency of Band 39, the configuration of Band 39, considering the equivalent input capacitance, is optimized. For instance, in the case of Band 7 and Band 41, the configuration of Band 39 is optimized when the equivalent input capacitance is 1.4 pF.

Since the passbands of Band 7 and Band 41 partially overlap, they are not used simultaneously. Thus, when either Band 7 or Band 41 is used individually, optimization can be performed independently by disconnecting Band 39.

When Band 39 is used individually, the capacitive element C is connected to replace the equivalent input capacitance of Band 7 or Band 41. This configuration accounts for the equivalent input capacitance and ensures that the optimized characteristics of Band 39 are maintained, allowing its performance to be fully realized.

It should be noted that in the front-end module 2 of Embodiment 2, the simultaneous use of Band 3 and Band 39 is not considered. This is because the passband frequencies of these two bands are too close to achieve proper impedance matching.

In another use case, the first elastic wave device BPF1 can be, for example, a bandpass filter for the receive band of Band 1, with a center frequency of 2140 MHz, allowing frequencies in the range of 2110 MHz to 2170 MHz to pass.

The fourth elastic wave device BPF4 can be, for example, a bandpass filter for the receive band of Band 34, with a center frequency of 2117.5 MHz, allowing frequencies in the range of 2110 MHz to 2125 MHz to pass.

The front-end module 6 of Embodiment 6, as described above, features a simplified structure that enables the construction of a front-end module supporting carrier aggregation while simplifying the design of equivalent input capacitances for bandpass filters.

### Embodiment 7

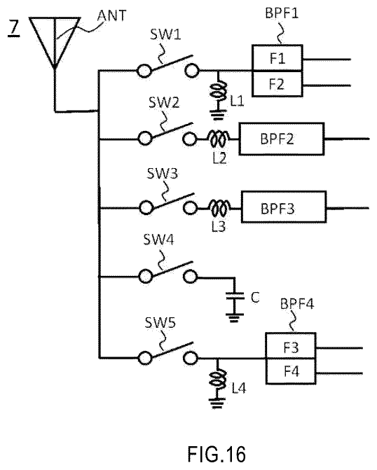

FIG. 16 illustrates a schematic diagram of the front-end module 7 in Embodiment 7. As shown in FIG. 16, the front-end module 7 builds upon the structure of the front-end module 6 described in Embodiment 6, with the addition of a first elastic wave device BPF1, which includes a first filter (F1) and a second filter (F2). Additionally, the fourth elastic wave device BPF4 includes a third filter (F3) and a fourth filter (F4).

The first filter F1, for example, is a bandpass filter for Band 3, with a center frequency of 1842.5 MHz, allowing frequencies in the range of 1805 MHz to 1880 MHz to pass.

The second filter F2, for example, is a bandpass filter for Band 1, with a center frequency of 2140 MHz, allowing frequencies in the range of 2110 MHz to 2170 MHz to pass.

As previously described, the second elastic wave device BPF2 is a bandpass filter for Band 7, with a center frequency of 2655 MHz, the third elastic wave device BPF3 is a bandpass filter for Band 41, with a center frequency of 2593 MHz. The average of the center frequencies of BPF2 and BPF3 is 2624 MHz.

The first filter F1 and the first inductor element L1 are designed to achieve an equivalent input capacitance, calculated using Equation 1, at the average center frequency of 2624 MHz, while satisfying subsequent conditions. Similarly, the second filter F2 and the first inductor element L1 are designed to meet the same requirements.

Since the frequency of the first filter F1 is lower than that of the second filter F2, the equivalent input capacitance of the first filter F1 is smaller at the average center frequency of 2624 MHz.

The third filter F3, for example, is a bandpass filter for Band 39, with a center frequency of 1900 MHz, allowing frequencies in the range of 1880 MHz to 1920 MHz to pass.

The fourth filter F4, for example, is a bandpass filter for Band 34, with a center frequency of 2117.5 MHz, allowing frequencies in the range of 2110 MHz to 2125 MHz to pass.

The center frequency of the first filter F1 (1805 MHz-1880 MHz) and the third filter F3 (1880 MHz-1920 MHz) is 1872 MHz.

The center frequency of the second filter F2 (2110 MHz-2170 MHz) and the fourth filter F4 (2110 MHz-2125 MHz) is 2129 MHz.

The third filter F3 and the fourth inductor element L4 are designed to achieve an equivalent input capacitance, calculated using the aforementioned Equation 1, at the average center frequency of 2624 MHz, while meeting the conditions described below.

Similarly, the fourth filter F4 and the fourth inductor element L4 are also designed to achieve an equivalent input capacitance, calculated using Equation 1, at the average center frequency of 2624 MHz, while satisfying the subsequent conditions.

Since the frequency of the third filter F3 is lower than that of the fourth filter F4, the equivalent input capacitance of the third filter F3 is smaller at the average center frequency of 2624 MHz.

The equivalent input capacitance of the second elastic wave device BPF2 at the center frequency of 1872 MHz (the average of the first filter F1 at 1805 MHz-1880 MHz and the third filter F3 at 1880 MHz-1920 MHz) is greater than the equivalent input capacitances of filters F1 to F4 at the average center frequency of 2624 MHz.

The equivalent input capacitance of the third elastic wave device BPF3 at the center frequency of 1872 MHz (the average of the first filter F1 at 1805 MHz-1880 MHz and the third filter F3 at 1880 MHz-1920 MHz) is greater than the equivalent input capacitances of filters F1 to F4 at the average center frequency of 2624 MHz.

At the center frequency of 1872 MHz (the average of the first filter F1 at 1805 MHz-1880 MHz and the third filter F3 at 1880 MHz-1920 MHz), the sum of the equivalent input capacitance of the second filter F2 or the fourth filter F4 and the equivalent input capacitance of the second elastic wave device BPF2 should ideally have an impedance absolute value equal to the impedance absolute value of the first inductor element L1 at 1872 MHz.

At the center frequency of 2129 MHz (the average of the second filter F2 at 2110 MHz-2170 MHz and the fourth filter F4 at 2110 MHz-2125 MHz), the sum of the equivalent input capacitance of the first filter F1 or the third filter F3 and the equivalent input capacitance of the second elastic wave device BPF2 should ideally have an impedance absolute value equal to the impedance absolute value of the first inductor element L1 at 2129 MHz.

At the average center frequency of 2624 MHz, the sum of the equivalent input capacitance of the first filter F1 or the third filter F3 and the equivalent input capacitance of the second filter F2 or the fourth filter F4 should ideally have an impedance absolute value equal to the impedance absolute value of the first inductor element L1 at 2624 MHz.

The front-end module 7 of Embodiment 7, as described above, maintains a simpler structure even when configured for six frequency bands. This allows for the construction of a front-end module that supports carrier aggregation while simplifying the design of equivalent input capacitances for bandpass filters.

While several aspects of at least one embodiment have been described, it should be understood that various modifications, adjustments, and improvements will be readily apparent to those skilled in the art. These modifications, adjustments, and improvements are intended to be part of this disclosure and fall within the scope of the present disclosure.

It should be understood that the embodiments of the methods and apparatus described herein are not limited to the structural and arrangement details of the components described in the above explanations or illustrated in the accompanying figures. The methods and apparatus can be implemented in other embodiments and may be executed or performed in various ways.

The specific embodiments are provided for illustrative purposes only and are not intended to be limiting. For example, the number of components installed within a module is not restricted to the numbers shown in the figures.

The expressions and terminology used in this disclosure are for explanatory purposes and should not be interpreted as limiting. The use of terms such as “comprise,” “include,” “have,” “contain,” and their variants are intended to cover the items listed thereafter as well as their equivalents and additional items.

References to terms such as “or” should be interpreted to mean that any one of the terms, multiple terms, or all of the terms described can apply.

Mentions of directions such as front, back, left, right, top, bottom, horizontal, vertical, inside, and outside are for descriptive convenience. These references do not limit the components of this disclosure to any specific orientation or spatial arrangement. Therefore, the above descriptions and illustrations are provided as examples only.

What is claimed is:

1. A front-end module, characterized by comprising:
an antenna terminal, a first elastic wave device, a second elastic wave device, a third elastic wave device, a capacitive element, a first switch, a second switch, a third switch, and a fourth switch;
the first elastic wave device is connected to the antenna terminal and is configured to pass a first frequency band;
the second elastic wave device is connected to the antenna terminal and is configured to pass a second frequency band;
the third elastic wave device is connected to the antenna terminal and is configured to pass a third frequency band;
the capacitive element is connected to the antenna terminal;
the first switch is configured to switch between a closed state and an open state between the antenna terminal and the first elastic wave device;
the second switch is configured to switch between a closed state and an open state between the antenna terminal and the second elastic wave device;
the third switch is configured to switch between a closed state and an open state between the antenna terminal and the third elastic wave device;
the fourth switch is configured to switch between a closed state and an open state between the antenna terminal and the capacitive element;
wherein the second frequency band and the third frequency band are higher in frequency than the first frequency band; the capacitive element is either a capacitor element or a resonator;
when the capacitive element is the resonator, the resonant frequency of the resonator is higher than the frequency of the first frequency band but lower than the frequencies of the second frequency band and the third frequency band.

2. The front-end module according to claim 1, wherein at least one of the first switch to the third switch is in a closed state, and the second frequency band and the third frequency band are either at least partially overlapping or adjacent to each other, and the second switch and the third switch are not simultaneously in a closed state.

3. The front-end module according to claim 2, wherein when the first switch is in a closed state and the second switch and the third switch are in open states, the fourth switch is in a closed state.

4. The front-end module according to claim 1, wherein the resonator is divided in parallel into a first split resonator and a second split resonator, wherein the resonant frequency of the first split resonator and the resonant frequency of the second split resonator are different.

5. The front-end module according to claim 1, wherein the resonator is a SAW resonator, at least one of the second elastic wave device and the third elastic wave device is an elastic wave device comprising a SAW filter with a piezoelectric substrate, and the resonator is formed on the piezoelectric substrate.

6. The front-end module according to claim 3, wherein it further comprises a fourth elastic wave device and a fifth switch; the fourth elastic wave device is connected to the antenna terminal; the fifth switch is configured to switch between a closed state and an open state between the antenna terminal and the fourth elastic wave device; the fourth frequency band is a frequency band lower than the second frequency band, and when the first switch or the fifth switch is closed and the second switch and the third switch are open, the fourth switch is closed.

7. The front-end module according to claim 6, wherein when only the fifth switch is closed, the fourth switch is closed.

8. The front-end module according to claim 6, wherein when the third switch and the fifth switch are closed, the fourth switch is open.

9. The front-end module according to claim 3, wherein it further comprises a first inductor element; the first inductor element is connected between the first switch and the first elastic wave device and is grounded.

10. The front-end module according to claim 3, wherein it further comprises a second inductor element and a third inductor element; the second inductor element is connected in series between the second switch and the second elastic wave device. the third inductor element is connected in series between the third switch and the third elastic wave device.

11. The front-end module according to claim 6, wherein it further comprises a fourth inductor element; the fourth inductor element is connected between the fifth switch and the fourth elastic wave device and is grounded.

12. The front-end module according to claim 3, wherein the equivalent input capacitance of the first elastic wave device at frequencies outside the second frequency band and the third frequency band is smaller than the equivalent input capacitance of the capacitive element.

13. The front-end module according to claim 3, wherein the equivalent input capacitance of the second elastic wave device and the equivalent input capacitance of the third elastic wave device are equal at the center frequency of the first frequency band.

14. The front-end module according to claim 3, wherein the equivalent input capacitance of the first elastic wave device at frequencies outside the first frequency band is smaller than the equivalent input capacitance of the second elastic wave device and the third elastic wave device.

15. The front-end module according to claim 6, wherein the equivalent input capacitance of the second elastic wave device and the equivalent input capacitance of the third elastic wave device are equal at the center frequency of the first frequency band and also equal at the center frequency of the fourth frequency band.

16. The front-end module according to claim 3, wherein the first elastic wave device comprises a first filter and a second filter; the first filter passes a first sub-band within the first frequency band; the second filter passes a second sub-band within the first frequency band, which is higher in frequency than the first sub-band; the equivalent input capacitance of the first filter at the average value of the center frequency of the second frequency band and the center frequency of the third frequency band (the average center frequency) is smaller than the equivalent input capacitance of the second filter.

17. The front-end module according to claim 6, wherein the first elastic wave device comprises a first filter and a second filter; the first filter passes a first sub-band within the first frequency band; the second filter passes a second sub-band within the first frequency band, which is higher in frequency than the first sub-band; the equivalent input capacitance of the first filter at the average value of the center frequency of the second frequency band and the center frequency of the third frequency band (the average center frequency) is smaller than the equivalent input capacitance of the second filter.

18. The front-end module according to claim 6, wherein the fourth elastic wave device comprises a third filter and a fourth filter; the third filter passes a third sub-band within the fourth frequency band; the fourth filter passes a fourth sub-band within the fourth frequency band, which is higher in frequency than the third sub-band; the equivalent input capacitance of the third filter at the average value of the center frequency of the second frequency band and the center frequency of the third frequency band is smaller than the equivalent input capacitance of the fourth filter.

19. The front-end module according to claim 5, wherein the resonator further comprises an interdigital transducer and a reflector formed on the piezoelectric substrate.

20. The front-end module according to claim 5, wherein the piezoelectric substrate is a lithium tantalate substrate or a lithium niobate substrate.
